(19) United States
(12) Patent Application Publication
(10) Pub. No.: US 2021/0193214 A1
(43) Pub. Date: Jun. 24, 2021

(54) SEMICONDUCTOR DEVICES

(71) Applicant: SK hynix Inc., Icheon-si Gyeonggi-do (KR)

(72) Inventors: Woongrae KIM, Icheon-si Gyeonggi-do (KR); So Min PARK, Icheon-si Gyeonggi-do (KR)

(73) Assignee: SK hynix Inc., Icheon-si Gyeonggi-do (KR)

(21) Appl. No.: 16/878,128

(22) Filed: May 19, 2020

(30) Foreign Application Priority Data
Dec. 19, 2019 (KR) 10-2019-0171268

(51) Int. Cl. G11C 11/408

(52) U.S. Cl. CPC G11C 11/4087

(57) ABSTRACT

A semiconductor device includes a bank group control circuit and a bank group. The bank group control circuit generates a bank group enablement signal, a first column control signal, and a second column control signal based on an internal command/address signal that is inputted while an internal chip selection signal has a first logic level. The bank group includes first to fourth banks and a common circuit. The common circuit performs a column operation for at least two of the first to fourth banks based on the bank group enablement signal and the first and second column control signals.

### CROSS-REFERENCE TO RELATED APPLICATIONS

The present application claims priority under 35 U.S.C 119(a) to Korean Application No. 10-2019-0171268, filed on Dec. 19, 2019, which is incorporated herein by reference in its entirety.

### BACKGROUND

### 1. Technical Field

Embodiments of the present disclosure relate to semiconductor devices including a plurality of banks sharing a circuit for performing a column operation.

### 2. Related Art

In general, each of semiconductor devices, such as dynamic random access memory (DRAM) devices, may include a plurality of bank groups that are comprised of cell arrays which are selected by addresses. Each of the bank groups may include a plurality of banks. The semiconductor device may select any one of the plurality of bank groups and may perform a column operation to output data, stored in a cell array, included in the selected bank group through input/output (I/O) lines.

### SUMMARY

According to an embodiment, a semiconductor device includes a bank group control circuit and a bank group. The bank group control circuit is configured to generate a bank group enablement signal, a first column control signal, and a second column control signal based on an internal command/address signal that is inputted while an internal chip selection signal has a first logic level. The bank group is configured to include first to fourth banks and a common circuit. The common circuit performs a column operation for at least two of the first to fourth banks based on the bank group enablement signal and the first and second column control signals.

According to another embodiment, a semiconductor device includes a bank group control circuit and a core circuit. The bank group control circuit is configured to generate a bank group enablement signal, a first column control signal, and a second column control signal based on an internal command/address signal that is inputted while an internal chip selection signal has a first logic level. The core circuit is configured to include a first bank group and a second bank group. After any one of a first common circuit and a second common circuit, the first common circuit and the second common circuit being connected to banks of the first bank group, is activated by the bank group enablement signal and the first and second column control signals to perform a column operation, any one of a third common circuit and a fourth common circuit, the third common circuit and fourth second common circuit being connected to banks of the second bank group, is activated by the bank group enablement signal and the first and second column control signals to perform the column operation.

### BRIEF DESCRIPTION OF THE DRAWINGS

FIG. 1 is a block diagram, illustrating a configuration of a semiconductor system, according to an embodiment of the present disclosure.

FIG. 2 is a block diagram, illustrating a configuration of a semiconductor device, included in the semiconductor system of FIG. 1.

FIG. 3 is a block diagram, illustrating a configuration of a bank group control circuit, included in the semiconductor device of FIG. 2.

FIG. 4 is a table, illustrating a chip selection signal and a command address for executing an operation of a semiconductor system, according to an embodiment of the present disclosure.

FIG. 5 is a block diagram, illustrating a configuration of an internal address generation circuit, included in the bank group control circuit of FIG. 3.

FIG. 6 is a block diagram, illustrating a configuration of an address transfer circuit, included in the internal address generation circuit of FIG. 5.

FIG. 7 is a circuit diagram, illustrating a configuration of a first address transfer circuit, included in the address transfer circuit of FIG. 6.

FIG. 8 is a circuit diagram, illustrating a configuration of a second address transfer circuit, included in the address transfer circuit of FIG. 6.

FIG. 9 is a block diagram, illustrating a configuration of a first bank group, included in the semiconductor device of FIG. 2.

FIG. 10 is a block diagram, illustrating a configuration of a third bank group, included in the semiconductor device of FIG. 2.

FIG. 11 is a timing diagram, illustrating a column operation performed during a write operation and a read operation of a semiconductor system, according to an embodiment of the present disclosure.

FIG. 12 is a block diagram, illustrating a configuration of an electronic system including the semiconductor system, shown in FIGS. 1 to 11.

### DETAILED DESCRIPTION OF THE EMBODIMENTS

In the following description of the embodiments, when a parameter is referred to as being “predetermined”, it may be intended to mean that a value of the parameter is determined in advance when the parameter is used in a process or an algorithm. The value of the parameter may be set when the process or the algorithm starts or may be set during a period that the process or the algorithm is executed.

In the following description of the embodiments, when a parameter is referred to as being “predetermined”, it may be intended to mean that a value of the parameter is determined in advance when the parameter is used in a process or an algorithm. The value of the parameter may be set when the process or the algorithm starts or may be set during a period that the process or the algorithm is executed.

It will be understood that although the terms “first”, “second”, “third” etc. are used herein to describe various elements, these elements should not be limited by these terms. These terms are only used to distinguish one element from another element. Thus, a first element in some embodiments could be termed a second element in other embodiments without departing from the teachings of the present disclosure.

Further, it will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A logic “high” level and a logic “low” level may be used to describe logic levels of electric signals. A signal with a logic “high” level may be distinguished from a signal with a logic “low” level. For example, when a signal with a first voltage correspond to a signal with a logic “high” level, a signal with a second voltage correspond to a signal with a logic “low” level. In an embodiment, the logic “high” level may be set as a voltage level which is higher than a voltage level of the logic “low” level. Meanwhile, logic levels of signals may be set to be different or opposite according to the embodiments. For example, a certain signal with a logic “high” level in one embodiment may be set to have a logic “low” level in another embodiment.

Various embodiments of the present disclosure will be described hereinafter in detail with reference to the accompanying drawings. However, the embodiments described herein are for illustrative purposes only and are not intended to limit the scope of the present disclosure.

In the present disclosure, semiconductor devices, such as low power double data rate 5 (LPDDR5) DRAM devices, may provide a bank group mode, an 8-bank mode, and a 16-bank mode. A bank group may include a plurality of banks. For example, the bank group may include four banks. In the bank group mode, a column operation for one bank that is included in the bank group may be performed by one command. In the 8-bank mode, column operations for two banks that are respectively included in separate bank groups may be sequentially performed by one command. In the 16-bank mode, column operations for four banks that are respectively included in separate bank groups may be sequentially performed by one command.

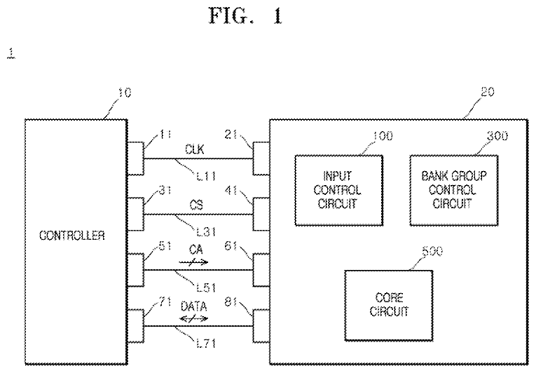

FIG. 1 is a block diagram, illustrating a configuration of a semiconductor system, according to an embodiment of the present disclosure. As illustrated in FIG. 1, a semiconductor system 1 includes a controller 10 and a semiconductor device 20. The semiconductor device 20 may include an input control circuit 100, a bank group control circuit 300, and a core circuit 500.

The controller 10 may include a first control pin 11, a second control pin 31, a third control pin 51, and a fourth control pin 71. The semiconductor device 20 may include a first semiconductor pin 21, a second semiconductor pin 41, a third semiconductor pin 61, and a fourth semiconductor pin 81. The first control pin 11 and the first semiconductor pin 21 may be connected to each other by a first transmission line L11. The second control pin 31 and the second semiconductor pin 41 may be connected to each other by a second transmission line L31. The third control pin 51 and the third semiconductor pin 61 may be connected to each other by a third transmission line L51. The fourth control pin 71 and the fourth semiconductor pin 81 may be connected to each other by a fourth transmission line L71. The controller 10 may transmit a clock signal CLK to the semiconductor device 20 through the first transmission line L11 to control the semiconductor device 20. The controller 10 may transmit a chip selection signal CS to the semiconductor device 20 through the second transmission line L31 to control the semiconductor device 20. The controller 10 may transmit a command/address signal CA to the semiconductor device 20 through the third transmission line L51 to control the semiconductor device 20. Finally, through the fourth transmission line L71, the controller 10 may receive data DATA from the semiconductor device 20 or may transmit the data DATA to the semiconductor device 20.

The controller 10 may output the clock signal CLK, the chip selection signal CS, the command/address signal CA, and the data DATA to the semiconductor device 20 to perform a write operation. The controller 10 may output the clock signal CLK, the chip selection signal CS, the command/address signal CA, and the data DATA to the semiconductor device 20 to perform a read operation. The controller 10 may receive the data DATA from the semiconductor device 20 during the read operation.

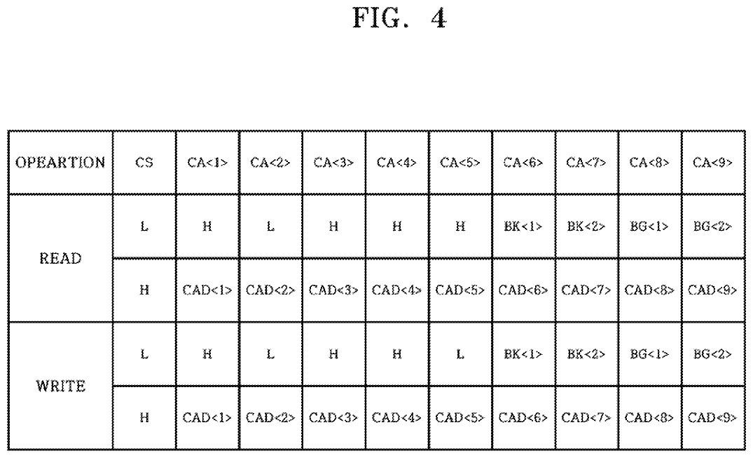

The logic levels of the chip selection signal CS and the command/address signal CA for executing the write operation and the read operation will be described in detail with reference to FIG. 4.

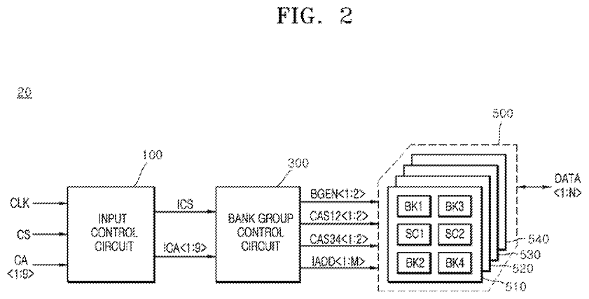

The input control circuit 100 may be synchronized with the clock signal CLK to generate an internal chip selection signal (ICS of FIG. 2) based on the chip selection signal CS. The input control circuit 100 may be synchronized with the clock signal CLK to generate an internal command/address signal (ICA<1:9> of FIG. 2) based on the command/address signal CA and the logic level of the chip selection signal CS.

The bank group control circuit 300 may generate a bank group enablement signal (BGEN<1:2> of FIG. 2), a first column control signal (CAS12<1:2> of FIG. 2), and a second column control signal (CAS34<1:2> of FIG. 2) based on the internal command/address signal ICA<1:9> that is inputted while the internal chip selection signal ICS has a first logic level (e.g., a logic “low” level). The bank group control circuit 300 may generate an internal address (IADD<1:M> of FIG. 2) based on the internal command/address signal ICA<1:9> that is inputted while the internal chip selection signal ICS has a second logic level (e.g., a logic “high” level).

The core circuit 500 may include first to fourth bank groups (510, 520, 530, and 540 of FIG. 2). The core circuit 500 may receive the bank group enablement signal (BGEN<1:2> of FIG. 2), the first column control signal (CAS12<1:2> of FIG. 2), and the second column control signal (CAS34<1:2> of FIG. 2) to activate common circuits that the banks, included in the first to fourth bank groups 510, 520, 530, and 540, share with each other. The core circuit 500 may perform a column operation based on the bank group enablement signal (BGEN<1:2> of FIG. 2), the first column control signal (CAS12<1:2> of FIG. 2), the second column control signal (CAS34<1:2> of FIG. 2), and the internal address (IADD<1:M> of FIG. 2).

FIG. 2 is a block diagram, illustrating a configuration of the semiconductor device 20. As illustrated in FIG. 2, the semiconductor device 20 may include the input control circuit 100, the bank group control circuit 300, and the core circuit 500.

The input control circuit 100 may be synchronized with a rising edge or a falling edge of the clock signal CLK to generate the internal chip selection signal ICS based on the chip selection signal CS. The input control circuit 100 may be synchronized with a rising edge or a falling edge of the clock signal CLK to generate the internal command/address signal ICA<1:9> based on the command/address signal CA<1:9>. The input control circuit 100 may be synchronized with a rising edge or a falling edge of the clock signal CLK to generate the internal command/address signal ICA<1:9> for generating the bank group enablement signal BGEN<1:2>, the first column control signal CAS12<1:2>, and the second column control signal CAS34<1:2> based on the command/address signal CA<1:9> while the chip selection signal CS has the first logic level (i.e., a logic “low” level). The input control circuit 100 may be synchronized with a rising edge or a falling edge of the clock signal CLK to generate the internal command/address signal ICA<1:9> for generating the internal address IADD<1:M> based on the command/address signal CA<1:9> while the chip selection signal CS has the second logic level (i.e., a logic “high” level).

The bank group control circuit 300 may generate the bank group enablement signal BGEN<1:2>, the first column control signal CAS12<1:2>, and the second column control signal CAS34<1:2> based on the internal command/address signal ICA<1:9> that is inputted while the internal chip selection signal ICS has the first logic level (i.e., a logic “low” level). The bank group control circuit 300 may generate the internal address IADD<1:M> based on the internal command/address signal ICA<1:9> that is inputted while the internal chip selection signal ICS has the second logic level (i.e., a logic “high” level).

The core circuit 500 may include the first to fourth bank groups 510, 520, 530, and 540. The core circuit 500 may receive the bank group enablement signal BGEN<1:2>, the first column control signal CAS12<1:2>, and the second column control signal CAS34<1:2> to activate common circuits, the common circuits being connected to the banks that are included in the first to fourth bank groups 510, 520, 530, and 540. The core circuit 500 may perform the column operation based on the bank group enablement signal BGEN<1:2>, the first column control signal CAS12<1:2>, the second column control signal CAS34<1:2>, and the internal address IADD<1:M>.

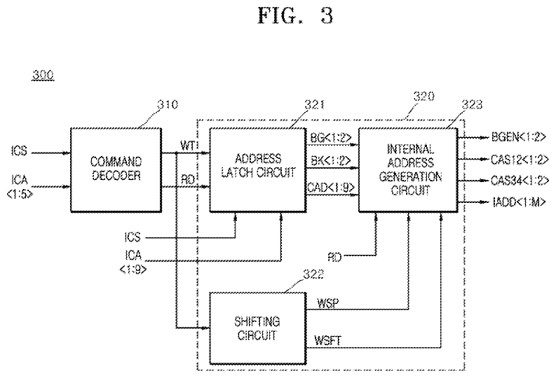

FIG. 3 is a block diagram, illustrating a configuration of the bank group control circuit 300. As illustrated in FIG. 3, the bank group control circuit 300 may include a command decoder 310 and a column control circuit 320.

The command decoder 310 may decode the internal chip selection signal ICS and the internal command/address signal ICA<1:9> to generate a write signal WT and a read signal RD, one of which is selectively enabled. Logic levels of the internal chip selection signal ICS and the internal command/address signal ICA<1:9> for generating the write signal WT and the read signal RD will be described in detail with reference to FIG. 4.

The column control circuit 320 may include an address latch circuit 321, a shifting circuit 322, and an internal address generation circuit 323.

The address latch circuit 321 may generate a bank group address BG<1:2> based on a first group ICA<8:9> of the internal command/address signal ICA<1:9> while the internal chip selection signal ICS has the first logic level (i.e., a logic “low” level) when any one of the write signal WT and the read signal RD is enabled. The address latch circuit 321 may generate a bank address BK<1:2> based on a second group ICA<6:7> of the internal command/address signal ICA<1:9> while the internal chip selection signal ICS has the first logic level (i.e., a logic “low” level) when any one of the write signal WT and the read signal RD is enabled. The address latch circuit 321 may generate an input command/address signal CAD<1:9> based on the internal command/address signal ICA<1:9> while the internal chip selection signal ICS has the second logic level (i.e., a logic “high” level) when any one of the write signal WT and the read signal RD is enabled.

The shifting circuit 322 may shift the write signal WT to generate a pre-shift signal WSP and a shift signal WSFT which are sequentially enabled. The shifting circuit 322 may shift the write signal WT by a predetermined period to generate the pre-shift signal WSP and may generate the shift signal WSFT after the pre-shift signal WSP is generated. The shift time of the shifting circuit 322 may be set to be a write latency. The write latency may be a time period from when a command for the write operation is inputted until the data is inputted. The shift time of the shifting circuit 322 may be set to be different according to the embodiments.

The internal address generation circuit 323 may generate the bank group enablement signal BGEN<1:2> based on the bank group address BG<1:2> when the read signal RD, the pre-shift signal WSP, and the shift signal WSFT are enabled. The internal address generation circuit 323 may generate the first column control signal CAS12<1:2> and the second column control signal CAS34<1:2> based on the bank address BK<1:2> when the read signal RD, the pre-shift signal WSP, and the shift signal WSFT are enabled. The internal address generation circuit 323 may generate the internal address IADD<1:M> based on the input command/address signal CAD<1:9> when the read signal RD, the pre-shift signal WSP, and the shift signal WSFT are enabled.

The internal address generation circuit 323 may generate the bank group enablement signal BGEN<1:2> based on the bank group address BG<1:2> when the read signal RD is enabled. The internal address generation circuit 323 may generate the first column control signal CAS12<1:2> and the second column control signal CAS34<1:2> based on the bank address BK<1:2> when the read signal RD is enabled. The internal address generation circuit 323 may generate the internal address IADD<1:M> based on the input command/address signal CAD<1:9> when the read signal RD is enabled.

The internal address generation circuit 323 may latch the bank group address BG<1:2>, the bank address BK<1:2>, and the input command/address signal CAD<1:9> when the pre-shift signal WSP is enabled. The internal address generation circuit 323 may generate the bank group enablement signal BGEN<1:2> based on the latched signal of the bank group address BG<1:2> when the shift signal WSFT is enabled. The internal address generation circuit 323 may generate the first column control signal CAS12<1:2> and the second column control signal CAS34<1:2> based on the latched signal of the bank address BK<1:2> when the shift signal WSFT is enabled. The internal address generation circuit 323 may generate the internal address IADD<1:M> based on the latched signal of the input command/address signal CAD<1:9> when the shift signal WSFT is enabled.

The column control circuit 320 with the aforementioned configuration may generate the bank group enablement signal BGEN<1:2>, the first column control signal CAS12<1:2>, the second column control signal CAS34<1:2>, and the internal address IADD<1:M> when the internal chip selection signal ICS and the internal command/address signal ICA<1:9> are inputted to the column control circuit 320 if the read signal RD is enabled. The column control circuit 320 may generate the bank group enablement signal BGEN<1:2>, the first column control signal CAS12<1:2>, the second column control signal CAS34<1:2>, and the internal address IADD<1:M> after a predetermined period when the internal chip selection signal ICS and the internal command/address signal ICA<1:9> are inputted to the column control circuit 320 if the write signal WT is enabled.

Logic level combinations of the chip selection signal CS and the command/address signal CA<1:9> for activating the read operation and the write operation will be described in detail hereinafter with reference to FIG. 4.

In advance of the descriptions, the chip selection signal CS may be set to have the same logic level as the internal chip selection signal ICS, and the command/address signal CA<1:9> may be set to have the same logic levels as the internal command/address signal ICA<1:9>.

First, the logic level combination of the chip selection signal CS and the command/address signal CA<1:9> for activating the read operation will be described hereinafter.

The read operation may be activated when a first bit signal CA<1> of the command/address signal CA<1:9> has the second logic level (i.e., a logic “high(H)” level), a second bit signal CA<2> of the command/address signal CA<1:9> has the first logic level (i.e., a logic “low(L)” level), a third bit signal CA<3> of the command/address signal CA<1:9> has the second logic level (i.e., a logic “high(H)” level), a fourth bit signal CA<4> of the command/address signal CA<1:9> has the second logic level (i.e., a logic “high(H)” level), and a fifth bit signal CA<5> of the command/address signal CA<1:9> has the second logic level (i.e., a logic “high(H)” level) in synchronization with the clock signal CLK while the chip selection signal CS has the first logic level (i.e., a logic “low(L)” level).

The command decoder 310 may generate the read signal RD, which is enabled by decoding the internal chip selection signal ICS, and the first to fifth bit signals ICA<1:5> of the internal command/address signal ICA<1:9>, which are generated to have the same logic levels as the first to fifth bit signals CA<1:5> of the command/address signal CA<1:9>, inputted while the chip selection signal CS has the first logic level (i.e., a logic “low(L)” level) during the read operation.

While the chip selection signal CS has the first logic level (i.e., a logic “low(L)” level) in synchronization with the clock signal CLK during the read operation, a sixth bit signal CA<6> of the command/address signal CA<1:9> may be set as a bit signal for generating a first bit signal BK<1> of the bank address BK<1:2>. While the chip selection signal CS has the first logic level (i.e., a logic “low(L)” level) in synchronization with the clock signal CLK during the read operation, a seventh bit signal CA<7> of the command/address signal CA<1:9> may be set as a bit signal for generating a second bit signal BK<2> of the bank address BK<1:2>.

While the chip selection signal CS has the first logic level (i.e., a logic “low(L)” level) in synchronization with the clock signal CLK during the read operation, an eighth bit signal CA<8> of the command/address signal CA<1:9> may be set as a bit signal for generating a first bit signal BG<1> of the bank group address BG<1:2>. While the chip selection signal CS has the first logic level (i.e., a logic “low(L)” level) in synchronization with the clock signal CLK during the read operation, a ninth bit signal CA<9> of the command/address signal CA<1:9> may be set as a bit signal for generating a second bit signal BG<2> of the bank group address BG<1:2>.

The sixth and seventh bit signals CA<6:7> of the command/address signal CA<1:9> may be set as a second group of the command/address signal CA<1:9>, and the eighth and ninth bit signals CA<8:9> of the command/address signal CA<1:9> may be set as a first group of the command/address signal CA<1:9>.

While the chip selection signal CS has the second logic level (i.e., a logic “high(H)” level) in synchronization with the clock signal CLK during the read operation, the first to ninth bit signals CA<1:9>of the command/address signal CA may be set as bit signals for generating first to ninth bit signal CAD<1:9> of the input command/address signal CAD.

Next, the logic level combination of the chip selection signal CS and the command/address signal CA<1:9> for activating the write operation will be described hereinafter.

The write operation may be activated when the first bit signal CA<1> of the command/address signal CA<1:9> has the second logic level (i.e., a logic “high(H)” level), the second bit signal CA<2>of the command/address signal CA<1:9> has the first logic level (i.e., a logic “low(L)” level), the third bit signal CA<3> of the command/address signal CA<1:9> has the second logic level (i.e., a logic “high(H)” level), the fourth bit signal CA<4> of the command/address signal CA<1:9> has the second logic level (i.e., a logic “high(H)” level), and the fifth bit signal CA<5> of the is command/address signal CA<1:9> has the first logic level (i.e., a logic “low(L)” level) in synchronization with the clock signal CLK while the chip selection signal CS has the first logic level (i.e., a logic “low(L)” level).

The command decoder 310 may generate the write signal WT, which is enabled by decoding the internal chip selection signal ICS, and the first to fifth bit signals ICA<1:5> of the internal command/address signal ICA<1:9>, which are generated to have the same logic levels as the first to fifth bit signals CA<1:5> of the command/address signal CA<1:9>, inputted while the chip selection signal CS has the first logic level (i.e., a logic “low(L)” level) during the write operation.

While the chip selection signal CS has the first logic level (i.e., a logic “low(L)” level) in synchronization with the clock signal CLK during the write operation, the sixth bit signal CA<6> of the command/address signal CA<1:9> may be set as a bit signal for generating the first bit signal BK<1> of the bank address BK<1:2>. While the chip selection signal CS has the first logic level (i.e., a logic “low(L)” level) in synchronization with the clock signal CLK during the write operation, the seventh bit signal CA<7> of the command/address signal CA<1:9> may be set as a bit signal for generating the second bit signal BK<2> of the bank address BK<1:2>.

While the chip selection signal CS has the first logic level (i.e., a logic “low(L)” level) in synchronization with the clock signal CLK during the write operation, the eighth bit signal CA<8> of the command/address signal CA<1:9> may be set as a bit signal for generating the first bit signal BG<1> of the bank group address BG<1:2>. While the chip selection signal CS has the first logic level (i.e., a logic “low(L)” level) in synchronization with the clock signal CLK during the write operation, the ninth bit signal CA<9> of the command/address signal CA<1:9> may be set as a bit signal for generating the second bit signal BG<2> of the bank group address BG<1:2>.

While the chip selection signal CS has the second logic level (i.e., a logic “high(H)” level) in synchronization with the clock signal CLK during the write operation, the first to ninth bit signals CA<1:9>of the command/address signal CA may be set as bit signals for generating first to ninth bit signal CAD<1:9> of the input command/address signal CAD.

Meanwhile, even in the following descriptions, a logic “low” level may correspond to the first logic level and a logic “high” level may correspond to the second logic level.

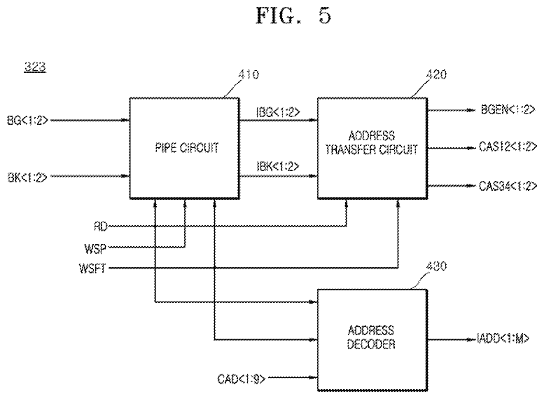

FIG. 5 is a block diagram, illustrating a configuration of the internal address generation circuit 323. As illustrated in FIG. 5, the internal address generation circuit 323 may include a pipe circuit 410, an address transfer circuit 420, and an address decoder 430.

The pipe circuit 410 may generate an internal bank group address IBG<1:2> and an internal bank address IBK<1:2> based on the bank group address BG<1:2> and the bank address BK<:2>when the read signal RD is enabled. The pipe circuit 410 may latch the bank group address BG<1:2> and the bank address BK<:2>when the pre-shift signal WSP is enabled. The pipe circuit 410 may generate the internal bank group address IBG<1:2> and the internal bank address IBK<1:2> based on the latched signals of the bank group address BG<1:2> and the bank address BK<:2> when the shift signal WSFT is enabled.

The address transfer circuit 420 may generate the bank group enablement signal BGEN<1:2> based on the internal bank group address IBG<1:2> when the read signal RD is enabled. The address transfer circuit 420 may generate the first column control signal CAS12<1:2> and the second column control signal CAS34<1:2> based on the internal bank address IBK<1:2> when the read signal RD is enabled. The address transfer circuit 420 may generate the bank group enablement signal BGEN<1:2> based on the internal bank group address IBG<1:2> when the shift signal WSFT is enabled. The address transfer circuit 420 may generate the first column control signal CAS12<1:2> and the second column control signal CAS34<1:2> based on the internal bank address IBK<1:2> when the shift signal WSFT is enabled.

The address decoder 430 may decode the input command/address signal CAD<1:9> to generate the internal address IADD<1:M> when the read signal RD is enabled. The address decoder 430 may decode the input command/address signal CAD<1:9> to generate the internal address IADD<1:M> when the shift signal WSFT is enabled.

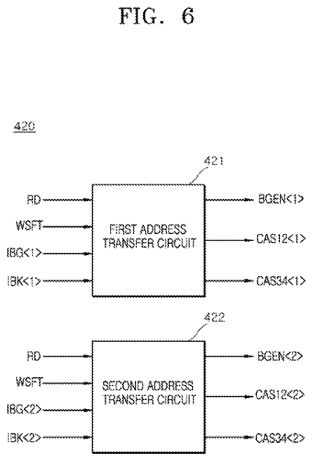

FIG. 6 is a block diagram, illustrating a configuration of the address transfer circuit 420. As illustrated in FIG. 6, the address transfer circuit 420 may include a first address transfer circuit 421 and a second address transfer circuit 422.

The first address transfer circuit 421 may generate a first bit signal BGEN<1> of the bank group enablement signal BGEN<1:2> based on a first bit signal IBG<1> of the internal bank group address IBG<1:2> when the read signal RD is enabled. The first address transfer circuit 421 may generate a first bit signal CAS12<1> of the first column control signal CAS12<1:2> and a first bit signal CAS34<1> of the second column control signal CAS34<1:2> based on a first bit signal IBK<1> of the internal bank address IBK<1:2> when the read signal RD is enabled. The first address transfer circuit 421 may generate the first bit signal BGEN<1> of the bank group enablement signal BGEN<1:2> based on the first bit signal IBG<1> of the internal bank group address IBG<1:2> when the shift signal WSFT is enabled. The first address transfer circuit 421 may generate the first bit signal CAS12<1> of the first column control signal CAS12<1:2> and the first bit signal CAS34<1> of the second column control signal CAS34<1:2> based on the first bit signal IBK<1> of the internal bank address IBK<1:2> when the shift signal WSFT is enabled.

The second address transfer circuit 422 may generate a second bit signal BGEN<2> of the bank group enablement signal BGEN<1:2> based on a second bit signal IBG<2> of the internal bank group address IBG<1:2> when the read signal RD is enabled.

The second address transfer circuit 422 may generate a second bit signal CAS12<2> of the first column control signal CAS12<1:2> and a second bit signal CAS34<2> of the second column control signal CAS34<1:2> based on a second bit signal IBK<2> of the internal bank address IBK<1:2> when the read signal RD is enabled. The second address transfer circuit 422 may generate the second bit signal BGEN<2> of the bank group enablement signal BGEN<1:2> based on the second bit signal IBG<2> of the internal bank group address IBG<1:2> when the shift signal WSFT is enabled. The second address transfer circuit 422 may generate the second bit signal CAS12<2> of the first column control signal CAS12<1:2> and the second bit signal CAS34<2> of the second column control signal CAS34<1:2> based on the second bit signal IBK<2> of the internal bank address IBK<1:2> when the shift signal WSFT is enabled.

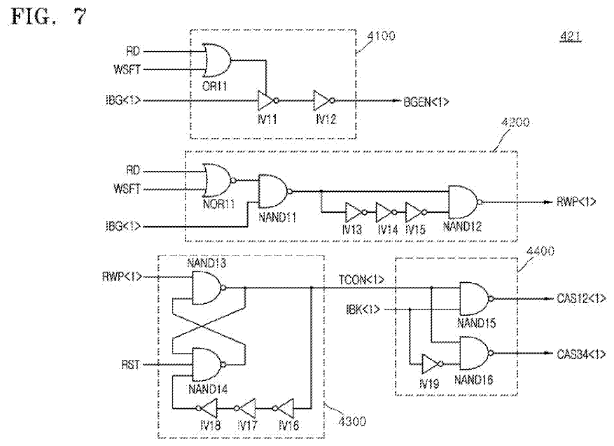

FIG. 7 is a circuit diagram, illustrating a configuration of the first address transfer circuit 421. As illustrated in FIG. 7, the first address transfer circuit 421 may include a first logic circuit 4100, a first pulse generation circuit 4200, a first latch circuit 4300, and a second logic circuit 4400.

The first logic circuit 4100 may perform an OR operation and inversion operations. For example, the first logic circuit 4100 may include an OR gate OR11 and inverters IV11 and IV12. The first logic circuit 4100 may buffer the first bit signal IBG<1> of the internal bank group address IBG<1:2> to generate the first bit signal

BGEN<1> of the bank group enablement signal BGEN<1:2> when the read signal RD is enabled to have a logic “high” level. The first logic circuit 4100 may buffer the first bit signal IBG<1> of the internal bank group address IBG<1:2> to generate the first bit signal BGEN<1> of the bank group enablement signal BGEN<1:2> when the shift signal WSFT is enabled.

The first pulse generation circuit 4200 may perform an NOR operation, NAND operations, and inversion operations. For example, the first pulse generation circuit 4200 may include a NOR gate NOR11, NAND gates NAND11 and NAND12, and inverters IV13, IV14, and IV15. The first pulse generation circuit 4200 may generate a first pulse signal RWP<1> including a pulse with a logic “low” level which is created when the read signal RD is enabled to have a logic “high” level and the first bit signal IBG<1> with a logic “low” level of the internal bank group address IBG<1:2> is inputted. The first pulse generation circuit 4200 may generate the first pulse signal RWP<1> including a pulse with a logic “low” level which is created when the shift signal WSFT is enabled to have a logic “high” level and the first bit signal IBG<1> with a logic “low” level of the internal bank group address IBG<1:2> is inputted.

The first latch circuit 4300 may perform NAND operations and inversion operations. For example, the first latch circuit 4300 may include NAND gates NAND13 and NAND14 and inverters IV16, IV17, and IV18. The first latch circuit 4300 may generate a first transfer control signal TCON<1> which is disabled to have a logic “low” level when a reset signal RST with a logic “low” level is inputted. The first latch circuit 4300 may generate the first transfer control signal TCON<1> which is enabled to have a logic “high” level when the first pulse signal RWP<1> has a logic “low” level. The first latch circuit 4300 may disable the first transfer control signal TCON<1> to a logic “low” level after a predetermined period elapses when the first transfer control signal TCON<1> is enabled to have a logic “high” level. The reset signal RST may be set as a signal including a pulse with a logic “low” level which is created when a reset operation is performed after the semiconductor system 1 operates.

The second logic circuit 4400 may perform an inversion operation and NAND operations. For example, the second logic circuit 4400 may include an inverter IV19 and NAND gates NAND15 and NAND16. The second logic circuit 4400 may generate the first bit signal CAS12<1> of the first column control signal CAS12<1:2> and the first bit signal CAS34<1> of the second column control signal CAS34<1:2>, one of which is selectively enabled based on a logic is level of the first bit signal IBK<1> of the internal bank address IBK<1:2> while the first transfer control signal TCON<1> is enabled to have a logic “high” level. The second logic circuit 4400 may generate the first bit signal CAS12<1> with a logic “high” level of the first column control signal CAS12<1:2> when the first bit signal IBK<1> of the internal bank address IBK<1:2> has a logic “low” level while the first transfer control signal TCON<1> is enabled to have a logic “high” level. The second logic circuit 4400 may generate the first bit signal CAS12<1> with a logic “low” level of the first column control signal CAS12<1:2> when the first bit signal IBK<1> of the internal bank address IBK<1:2> has a logic “high” level while the first transfer control signal TCON<1> is enabled to have a logic “high” level. The second logic circuit 4400 may generate the first bit signal CAS34<1> with a logic “low” level of the second column control signal CAS34<1:2> when the first bit signal IBK<1> of the internal bank address IBK<1:2> has a logic “low” level while the first transfer control signal TCON<1> is enabled to have a logic “high” level. The second logic circuit 4400 may generate the first bit signal CAS34<1> with a logic “high” level of the second column control signal CAS34<1:2> when the first bit signal IBK<1> of the internal bank address IBK<1:2> has a logic “high” level while the first transfer control signal TCON<1> is enabled to have a logic “high” level. The second logic circuit 4400 may generate the first bit signal CAS12<1> with a logic “high” level of the first column control signal CAS12<1:2> and the first bit signal CAS34<1> with a logic “high” level of the second column control signal CAS34<1:2> while the first transfer control signal TCON<1> is disabled to have a logic “low” level.

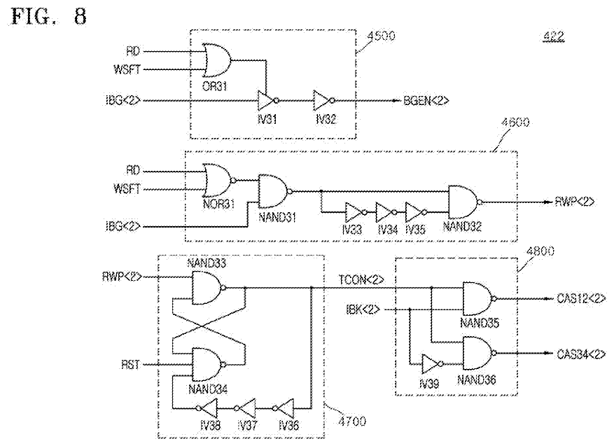

FIG. 8 is a circuit diagram illustrating a configuration of the second address transfer circuit 422. As illustrated in FIG. 8, the second address transfer circuit 422 may include a third logic circuit 4500, a second pulse generation circuit 4600, a second latch circuit 4700, and a fourth logic circuit 4800.

The third logic circuit 4500 may perform an OR operation and inversion operations. For example, the third logic circuit 4500 may include an OR gate OR31 and inverters IV31 and IV32. The third logic circuit 4500 may buffer the second bit signal IBG<2> of the internal bank group address IBG<1:2> to generate the second bit signal BGEN<2> of the bank group enablement signal BGEN<1:2> when the read signal RD is enabled to have a logic “high” level. The third logic circuit 4500 may buffer the second bit signal IBG<2> of the internal bank group address IBG<1:2> to generate the second bit signal BGEN<2> of the bank group enablement signal BGEN<1:2> when the shift signal WSFT is enabled.

The second pulse generation circuit 4600 may perform a NOR operation, NAND operations, and inversion operations. For example, the second pulse generation circuit 4600 may include a NOR gate NOR31, NAND gates NAND31 and NAND32, and inverters IV33, IV34, and IV35. The second pulse generation circuit 4600 may generate a second pulse signal RWP<2> including a pulse with a logic “low” level which is created when the read signal RD is enabled to have a logic “high” level and the second bit signal IBG<2> with a logic “low” level of the internal bank group address IBG<1:2> is inputted. The second pulse generation circuit 4600 may generate the second pulse signal RWP<2> including a pulse with a logic “low” level which is created when the shift signal WSFT is enabled to have a logic “high” level and the second bit signal IBG<2> with a logic “low” level of the internal bank group address IBG<1:2> is inputted.

The second latch circuit 4700 may perform NAND operations and inversion operations. For example, the second latch circuit 4700 may include NAND gates NAND33 and NAND34 and inverters IV36, IV37, and IV38. The second latch circuit 4700 may generate a second transfer control signal TCON<2> which is disabled to have a logic “low” level when the reset signal RST with a logic “low” level is inputted. The second latch circuit 4700 may generate the second transfer control signal TCON<2> which is enabled to have a logic “high” level when the second pulse signal RWP<2> has a logic “low” level. The second latch circuit 4700 may disable the second transfer control signal TCON<2> to a logic “low” level after a predetermined period elapses when the second transfer control signal TCON<2> is enabled to have a logic “high” level.

The fourth logic circuit 4800 may perform an inversion operation and NAND operations. For example, the fourth logic circuit 4800 may include an inverter IV39 and NAND gates NAND35 and NAND36. The fourth logic circuit 4800 may generate the second bit signal CAS12<2> of the first column control signal CAS12<1:2> and the second bit signal CAS34<1> of the second column control signal CAS34<1:2>, one of which is selectively enabled based on a logic level of the second bit signal IBK<2> of the internal bank address IBK<1:2> while the second transfer control signal TCON<2> is enabled to have a logic “high” level. The fourth logic circuit 4800 may generate the second bit signal CAS12<2> with a logic “high” level of the first column control signal CAS12<1:2> when the second bit signal IBK<2> of the internal bank address IBK<1:2> has a logic “low” level while the second transfer control signal TCON<2> is enabled to have a logic “high” level. The fourth logic circuit 4800 may generate the second bit signal CAS12<2> with a logic “low” level of the first column control signal CAS12<1:2> when the second bit signal IBK<2> of the internal bank address IBK<1:2> has a logic “high” level while the second transfer control signal TCON<2> is enabled to have a logic “high” level. The fourth logic circuit 4800 may generate the second bit signal CAS34<2> with a logic “low” level of the second column control signal CAS34<1:2> when the second bit signal IBK<2> of the internal bank address IBK<1:2> has a logic “low” level while the second transfer control signal TCON<2>is enabled to have a logic “high” level. The fourth logic circuit 4800 is may generate the second bit signal CAS34<2> with a logic “high” level of the second column control signal CAS34<1:2> when the second bit signal IBK<2> of the internal bank address IBK<1:2> has a logic “high” level while the second transfer control signal TCON<2>is enabled to have a logic “high” level. The fourth logic circuit 4800 may generate the second bit signal CAS12<2> with a logic “high” level of the first column control signal CAS12<1:2> and the second bit signal CAS34<2> with a logic “high” level of the second column control signal CAS34<1:2> while the second transfer control signal TCON<2> is disabled to have a logic “low” level.

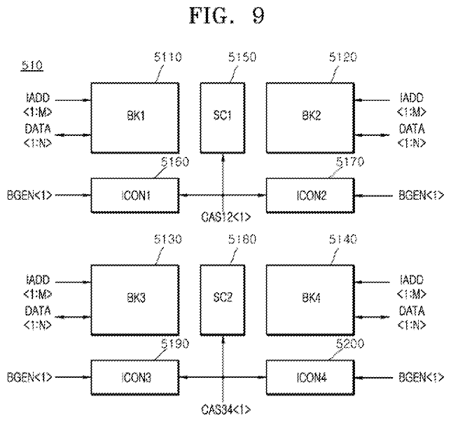

FIG. 9 is a block diagram illustrating a configuration of the first bank group 510. As illustrated in FIG. 9, the first bank group 510 may include a first bank 5110, a second bank 5120, a third bank 5130, a fourth bank 5140, a first common circuit 5150, a first internal control circuit 5160, a second internal control circuit 5170, a second common circuit 5180, a third internal control circuit 5190, and a fourth internal control circuit 5200.

The first bank 5110 may store the data DATA<1:N> into memory cells (not shown) which are selected by the internal address IADD<1:M> during the write operation. The first bank 5110 may output the data DATA<1:N> stored in the memory cells (not shown) which are selected by the internal address IADD<1:M> during the read operation.

The second bank 5120 may store the data DATA<1:N> into memory cells (not shown) which are selected by the internal address IADD<1:M> during the write operation. The second bank 5120 may output the data DATA<1:N> stored in the memory cells (not shown) which are selected by the internal address IADD<1:M> during the read operation.

The third bank 5130 may store the data DATA<1:N> into memory cells (not shown) which are selected by the internal address IADD<1:M> during the write operation. The third bank 5130 may output the data DATA<1:N> stored in the memory cells (not shown) which are selected by the internal address IADD<1:M> during the read operation.

The fourth bank 5140 may store the data DATA<1:N> into memory cells (not shown) which are selected by the internal address IADD<1:M> during the write operation. The fourth bank 5140 may output the data DATA<1:N> stored in the memory cells (not shown) which are selected by the internal address IADD<1:M> during the read operation.

The first common circuit 5150 may be activated to perform the column operations for the first and second banks 5110 and 5120 when the first bit signal CAS12<1> of the first column control signal CAS12<1:2> has a logic “low” level.

The first internal control circuit 5160 may be activated to perform the column operation for the first bank 5110 when the first bit signal CAS12<1> of the first column control signal CAS12<1:2>has a logic “low” level and the first bit signal BGEN<1> of the bank group enablement signal BGEN<1:2> has a logic “low” level.

The second internal control circuit 5170 may be activated to perform the column operation for the second bank 5120 when the first bit signal CAS12<1> of the first column control signal CAS12<1:2> has a logic “low” level and the first bit signal BGEN<1>of the bank group enablement signal BGEN<1:2> has a logic “high” level.

The second common circuit 5180 may be activated to perform the column operations for the third and fourth banks 5130 and 5140 when the first bit signal CAS34<1> of the second column control signal CAS34<1:2> has a logic “low” level.

The third internal control circuit 5190 may be activated to perform the column operation for the third bank 5130 when the first bit signal CAS34<1> of the second column control signal CAS34<1:2> has a logic “low” level and the first bit signal BGEN<1> of the bank group enablement signal BGEN<1:2> has a logic “low” level.

The fourth internal control circuit 5200 may be activated to perform the column operation for the fourth bank 5140 when the first bit signal CAS34<1> of the second column control signal CAS34<1:2> has a logic “low” level and the first bit signal BGEN<1> of the bank group enablement signal BGEN<1:2> has a logic “high” level.

The second bank group 520 may include a third common circuit (not shown), a fifth internal control circuit (not shown), and a sixth internal control circuit (not shown), which are activated to perform the column operations for some of banks that are included in the second bank group 520 when the first bit signal CAS12<1> of the first column control signal CAS12<1:2> has a logic “high” level.

In addition, the second bank group 520 may include a fourth common circuit (not shown), a seventh internal control circuit (not shown), and an eighth internal control circuit (not shown), which are activated to perform the column operations for the remaining banks of the banks that are included in the second bank group 520 when the first bit signal CAS34<1> of the second column control signal CAS34<1:2> has a logic “high” level.

Meanwhile, the column operations for the second bank group 520 may be performed after the column operations for the first bank group 510 terminate.

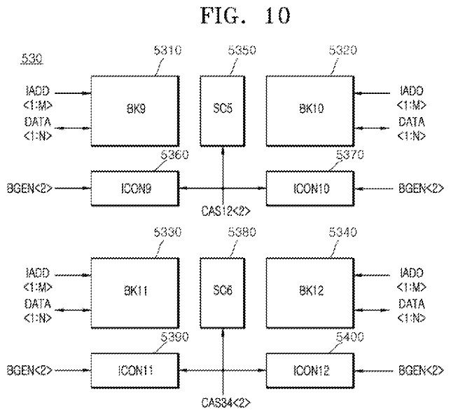

FIG. 10 is a block diagram illustrating a configuration of the third bank group 530. As illustrated in FIG. 10, the third bank group 530 may include a ninth bank 5310, a tenth bank 5320, an eleventh bank 5330, a twelfth bank 5340, a fifth common circuit 5350, a ninth internal control circuit 5360, a tenth internal control circuit 5370, a sixth common circuit 5380, an eleventh internal control circuit 5390, and a twelfth internal control circuit 5400.

The ninth bank 5310 may store the data DATA<1:N> into memory cells (not shown) which are selected by the internal address IADD<1:M> during the write operation. The ninth bank 5310 may output the data DATA<1:N> stored in the memory cells (not shown) which are selected by the internal address IADD<1:M> during the read operation.

The tenth bank 5320 may store the data DATA<1:N> into memory cells (not shown) which are selected by the internal address IADD<1:M> during the write operation. The tenth bank 5320 may output the data DATA<1:N> stored in the memory cells (not shown) which are selected by the internal address IADD<1:M> during the read operation.

The eleventh bank 5330 may store the data DATA<1:N> into memory cells (not shown) which are selected by the internal address IADD<1:M> during the write operation. The eleventh bank 5330 may output the data DATA<1:N> stored in the memory cells (not shown) which are selected by the internal address IADD<1:M>during the read operation.

The twelfth bank 5340 may store the data DATA<1:N> into memory cells (not shown) which are selected by the internal address IADD<1:M> during the write operation. The twelfth bank 5340 may output the data DATA<1:N> stored in the memory cells (not shown) which are selected by the internal address IADD<1:M> during the read operation.

The fifth common circuit 5350 may be activated to perform the column operations for the ninth and tenth banks 5310 and 5320 when the second bit signal CAS12<2> of the first column control signal CAS12<1:2> has a logic “low” level.

The ninth internal control circuit 5360 may be activated to perform the column operation for the ninth bank 5310 when the second bit signal CAS12<2> of the first column control signal CAS12<1:2> has a logic “low” level and the second bit signal BGEN<2> of the bank group enablement signal BGEN<1:2> has a logic “low” level.

The tenth internal control circuit 5370 may be activated to perform the column operation for the tenth bank 5320 when the second bit signal CAS12<2> of the first column control signal CAS12<1:2> has a logic “low” level and the second bit signal BGEN<2> of the bank group enablement signal BGEN<1:2> has a logic “high” level.

The sixth common circuit 5380 may be activated to perform the column operations for the eleventh and twelfth banks 5330 and 5340 when the second bit signal CAS34<2> of the second column control signal CAS34<1:2> has a logic “low” level.

The eleventh internal control circuit 5390 may be activated to perform the column operation for the eleventh bank 5330 when the second bit signal CAS34<2> of the second column control signal CAS34<1:2> has a logic “low” level and the second bit signal BGEN<2> of the bank group enablement signal BGEN<1:2>has a logic “low” level.

The twelfth internal control circuit 5400 may be activated to perform the column operation for the twelfth bank 5340 when the second bit signal CAS34<2> of the second column control signal CAS34<1:2> has a logic “low” level and the second bit signal BGEN<2> of the bank group enablement signal BGEN<1:2> has a logic “high” level.

The fourth bank group 540 may include a seventh common circuit (not shown), a thirteenth internal control circuit (not shown), and a fourteenth internal control circuit (not shown), which are activated to perform the column operations for some of banks that are included in the fourth bank group 540 when the second bit signal CAS12<2> of the first column control signal CAS12<1:2> has a logic “high” level. In addition, the fourth bank group 540 may include an eighth common circuit (not shown), a fifteenth internal control circuit (not shown), and a sixteenth internal control circuit (not shown), which are activated to perform the column operations for the remaining banks of the banks, that are included in the fourth bank group 540 when the second bit signal CAS34<2> of the second column control signal CAS34<1:2> has a logic “high” level.

Meanwhile, the column operations for the fourth bank group 540 may be performed after the column operations for the third bank group 530 terminate.

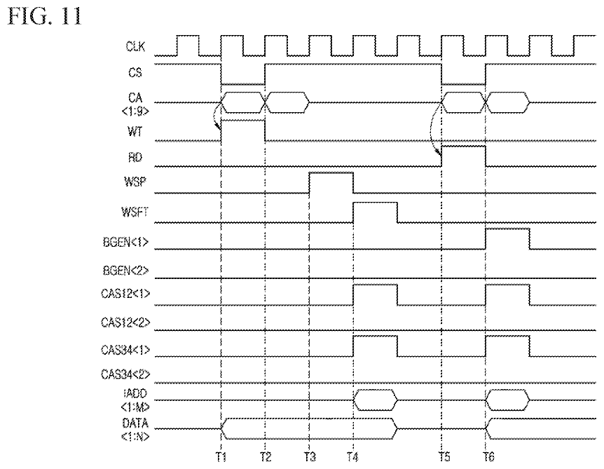

The column operations for the second bank group 520 and the third bank group 530 during the read operation of the semiconductor system 1 performed after the column operations for the second bank group 520 and the third bank group 530 during the write operation will be described hereinafter with reference to FIG. 11.

At time “T1”, the controller 10 may output the clock signal CLK, the chip selection signal CS with a logic “low” level, the command/address signal CA<1:9>, and the data DATA<1:16> for performing the write operation.

The input control circuit 100 may be synchronized with a rising edge of the clock signal CLK to generate the internal chip selection signal ICS with a logic “low” level based on the chip selection signal CS and to generate the internal command/address signal ICA<1:9> based on the command/address signal CA<1:9>.

The command decoder 310 may decode the internal chip selection signal ICS with a logic “low” level and the internal command/address signal ICA<1:9> to generate the write signal WT which is enabled to have a logic “high” level.

At time “T2”, the controller 10 may output the command/address signal CA<1:9> for performing the write operation.

The input control circuit 100 may be synchronized with a rising edge of the clock signal CLK to generate the internal command/address signal ICA<1:9> based on the command/address signal CA<1:9>.

The address latch circuit 321 may receive the write signal WT with a logic “high” level generated at time “T1” to generate the bank group address BG<1:2> based on the first group ICA<8:9>of the internal command/address signal ICA<1:9> that is inputted while the internal chip selection signal ICS has a logic “low” level.

The address latch circuit 321 may receive the write signal WT with a logic “high” level generated at time “T1” to generate the bank address BK<1:2> based on the second group ICA<6:7> of the internal command/address signal ICA<1:9> that is inputted while the internal chip selection signal ICS has a logic “low” level. The address latch circuit 321 may receive the write signal WT with a logic “high” level generated at time “T1” to generate the input command/address signal CAD<1:9> based on the internal command/address signal ICA<1:9> while the internal chip selection signal ICS has a logic “high” level.

At time “T3”, the shifting circuit 322 may shift the write signal WT generated at time “T1” to generate the pre-shift signal WSP which is enabled to have a logic “high” level.

The internal address generation circuit 323 may receive the pre-shift signal WSP with a logic “high” level to latch the bank group address BG<1:2>, the bank address BK<1:2>, and the input command/address signal CAD<1:9>.

At time “T4”, the shifting circuit 322 may shift the pre-shift signal WSP to generate the shift signal WSFT which is enabled to have a logic “high” level.

The internal address generation circuit 323 may receive the shift signal WSFT with a logic “high” level to generate the first bit signal BGEN<1> with a logic “low” level of the bank group enablement signal BGEN<1:2> and the second bit signal BGEN<2> with a logic “low” level of the bank group enablement signal BGEN<1:2> based on the bank group address BG<1:2>. The internal address generation circuit 323 may receive the shift signal WSFT with a logic “high” level to generate the first bit signal CAS12<1> with a logic “high” level of the first column control signal CAS12<1:2> and the second bit signal CAS12<2> with a logic “low” level of the first column control signal CAS12<1:2> based on the bank address BK<1:2>. The internal address generation circuit 323 may receive the shift signal WSFT with a logic “high” level to generate the first bit signal CAS34<1> with a logic “high” level of the second column control signal CAS34<1:2> and the second bit signal CAS34<2> with a logic “low” level of the second column control signal CAS34<1:2> based on the bank address BK<1:2>. The internal address generation circuit 323 may receive the shift signal WSFT with a logic “high” level to generate the internal address IADD<1:M> based on the input command/address signal CAD<1:9>.

A third common circuit (not shown) of the second bank group 520 may be activated by the first bit signal CAS12<1> with a logic “high” level of the first column control signal CAS12<1:2> to perform the column operation for a fifth bank (not shown).

A fifth internal control circuit (not shown) of the second bank group 520 may be activated by the first bit signal CAS12<1> with a logic “high” level of the first column control signal CAS12<1:2> and the first bit signal BGEN<1> with a logic “low” level of the bank group enablement signal BGEN<1:2> to perform the column operation for the fifth bank (not shown).

The fifth bank (not shown) of the second bank group 520 may store the data DATA<1:N> into memory cells (not shown) which are selected by the internal address IADD<1:M>.

A fourth common circuit (not shown) of the second bank group 520 may be activated by the first bit signal CAS34<1> with a logic “high” level of the second column control signal CAS34<1:2> to perform the column operation for a seventh bank (not shown).

A seventh internal control circuit (not shown) of the second bank group 520 may be activated by the first bit signal CAS34<1> with a logic “high” level of the second column control signal CAS34<1:2> and the first bit signal BGEN<1> with a logic “low” level of the bank group enablement signal BGEN<1:2> to perform the column operation for the seventh bank (not shown).

The seventh bank (not shown) of the second bank group 520 may store the data DATA<1:N> into memory cells (not shown) which are selected by the internal address IADD<1:M>.

A fifth common circuit (not shown) of the third bank group 530 may be activated by the second bit signal CAS12<2> with a logic “low” level of the first column control signal CAS12<1:2> to perform the column operation for the ninth bank 5310.

The ninth internal control circuit 5360 of the third bank group 530 may be activated by the second bit signal CAS12<2> with a logic “low” level of the first column control signal CAS12<1:2> and the second bit signal BGEN<2> with a logic “low” level of the bank group enablement signal BGEN<1:2> to perform the column operation for the ninth bank 5310.

The ninth bank 5310 of the third bank group 530 may store the data DATA<1:N> into memory cells (not shown) which are selected by the internal address IADD<1:M>.

The sixth common circuit 5380 of the third bank group 530 may be activated by the second bit signal CAS34<2> with a logic “low” level of the second column control signal CAS34<1:2> to perform the column operation for the eleventh bank 5330.

The eleventh internal control circuit 5390 of the third bank group 530 may be activated by the second bit signal CAS34<2> with a logic “low” level of the second column control signal CAS34<1:2> and the second bit signal BGEN<2> with a logic “low” level of the bank group enablement signal BGEN<1:2> to perform the column operation for the eleventh bank 5330.

The eleventh bank 5330 of the third bank group 530 is may store the data DATA<1:N> into memory cells (not shown) which are selected by the internal address IADD<1:M>.

At time “T5”, the controller 10 may output the clock signal CLK, the chip selection signal CS with a logic “low” level, and the command/address signal CA<1:9> for performing the read operation.

The input control circuit 100 may be synchronized with a rising edge of the clock signal CLK to generate the internal chip selection signal ICS with a logic “low” level based on the chip selection signal CS and to generate the internal command/address signal ICA<1:9> based on the command/address signal CA<1:9>.

The command decoder 310 may decode the internal chip selection signal ICS with a logic “low” level and the internal command/address signal ICA<1:9> to generate the read signal RD which is enabled to have a logic “high” level.

At time “T6”, the controller 10 may output the command/address signal CA<1:9> for performing the read operation.

The address latch circuit 321 may receive the read signal RD with a logic “high” level generated at time “T5” to generate the bank group address BG<1:2> based on the first group ICA<8:9> of the internal command/address signal ICA<1:9> that is inputted while the internal chip selection signal ICS has a logic “low” level. The address latch circuit 321 may receive the read signal RD with a logic “high” level generated at time “T5” to generate the bank address BK<1:2> based on the second group ICA<6:7> of the is internal command/address signal ICA<1:9> that is inputted while the internal chip selection signal ICS has a logic “low” level. The address latch circuit 321 may receive the read signal RD with a logic “high” level generated at time “T5” to generate the input command/address signal CAD<1:9> based on the internal command/address signal ICA<1:9> while the internal chip selection signal ICS has a logic “high” level.

The internal address generation circuit 323 may receive the read signal RD with a logic “high” level generated at time “T5” to generate the first bit signal BGEN<1> with a logic “high” level of the bank group enablement signal BGEN<1:2> and the second bit signal BGEN<2> with a logic “low” level of the bank group enablement signal BGEN<1:2> based on the bank group address BG<1:2>. The internal address generation circuit 323 may receive the read signal RD with a logic “high” level generated at time “T5” to generate the first bit signal CAS12<1> with a logic “high” level of the first column control signal CAS12<1:2> and the second bit signal CAS12<2> with a logic “low” level of the first column control signal CAS12<1:2> based on the bank address BK<1:2>. The internal address generation circuit 323 may receive the read signal RD with a logic “high” level generated at time “T5” to generate the first bit signal CAS34<1> with a logic “high” level of the second column control signal CAS34<1:2> and the second bit signal CAS34<2> with a logic “low” level of the second column control signal CAS34<1:2> based on the bank address BK<1:2>. The internal address generation circuit 323 may receive the read signal RD with a logic “high” level generated at time “T5” to generate the internal address IADD<1:M> based on the input command/address signal CAD<1:9>.

The third common circuit (not shown) of the second bank group 520 may be activated by the first bit signal CAS12<1> with a logic “high” level of the first column control signal CAS12<1:2> to perform the column operation for a sixth bank (not shown).

A sixth internal control circuit (not shown) of the second bank group 520 may be activated by the first bit signal CAS12<1> with a logic “high” level of the first column control signal CAS12<1:2> and the first bit signal BGEN<1> with a logic “high” level of the bank group enablement signal BGEN<1:2> to perform the column operation for the sixth bank (not shown).

The sixth bank (not shown) of the second bank group 520 may output the data DATA<1:N> stored in memory cells (not shown) which are selected by the internal address IADD<1:M>.

The fourth common circuit (not shown) of the second bank group 520 may be activated by the first bit signal CAS34<1> with a logic “high” level of the second column control signal CAS34<1:2> to perform the column operation for an eighth bank (not shown).

An eighth internal control circuit (not shown) of the second bank group 520 may be activated by the first bit signal CAS34<1> with a logic “high” level of the second column control signal CAS34<1:2> and the first bit signal BGEN<1> with a logic “high” level of the bank group enablement signal BGEN<1:2> to perform the column operation for the eighth bank (not shown).

The eighth bank (not shown) of the second bank group 520 may output the data DATA<1:N> stored in memory cells (not shown) which are selected by the internal address IADD<1:M>.

The fifth common circuit 5350 of the third bank group 530 may be activated by the second bit signal CAS12<2> with a logic “low” level of the first column control signal CAS12<1:2> to perform the column operation for the ninth bank 5310.

The ninth internal control circuit 5360 of the third bank group 530 may be activated by the second bit signal CAS12<2> with a logic “low” level of the first column control signal CAS12<1:2> and the second bit signal BGEN<2> with a logic “low” level of the bank group enablement signal BGEN<1:2> to perform the column operation for the ninth bank 5310.

The ninth bank 5310 of the third bank group 530 may output the data DATA<1:N> stored in memory cells (not shown) which are selected by the internal address IADD<1:M>.

The sixth common circuit 5380 of the third bank group 530 may be activated by the second bit signal CAS34<2> with a logic “low” level of the second column control signal CAS34<1:2> to perform the column operation for the eleventh bank 5330.

The eleventh internal control circuit 5390 of the third bank group 530 may be activated by the second bit signal CAS34<2> with a logic “low” level of the second column control signal CAS34<1:2> and the second bit signal BGEN<2> with a logic “low” level of the bank group enablement signal BGEN<1:2> to perform the column operation for the eleventh bank 5330.

The eleventh bank 5330 of the third bank group 530 may output the data DATA<1:N> stored in memory cells (not shown) which are selected by the internal address IADD<1:M>.

The controller 10 may receive the data DATA<1:N>.

According to the semiconductor system 1 described above, a plurality of banks that is included in each bank group may share a circuit for performing a column operation with each other to reduce a layout area of the semiconductor system 1. In addition, the semiconductor system 1 may generate signals for performing the column operations for banks that are included in each bank group at different points in time during the read operation and the write operation, thereby efficiently performing the column operations.

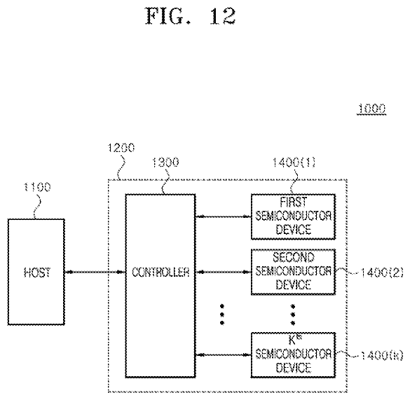

FIG. 12 is a block diagram illustrating a configuration of an electronic system 1000 according to an embodiment of the present disclosure. As illustrated in FIG. 12, the electronic system 1000 may include a host 1100 and a semiconductor system 1200.

The host 1100 and the semiconductor system 1200 may transmit signals to each other using an interface protocol. The interface protocol used for communication between the host 1100 and the semiconductor system 1200 may include any one of various interface protocols such as a multi-media card (MMC), an enhanced small device interface (ESDI), an integrated drive electronics (IDE), a peripheral component interconnect-express (PCI-E), an advanced technology attachment (ATA), a serial ATA (SATA), a parallel ATA (PATA), a serial attached SCSI (SAS), and a universal serial bus (USB).

The semiconductor system 1200 may include a controller 1300 and semiconductor devices 1400(K:1). The controller 1300 may control the semiconductor devices 1400(K:1) such that the semiconductor devices 1400(K:1) perform the write operation and the read operation. Each of the semiconductor devices 1400(K:1) may include a plurality of bank groups, and each of the bank groups may include a plurality of banks sharing a common circuit for performing the column operations for the plurality of banks. Thus, a layout area of each of the semiconductor devices 1400(K:1) may be reduced to provide a compact semiconductor device. Each of the semiconductor devices 1400(K:1) may generate signals for performing the column operations for banks that are included in each bank group at different points in time during the read operation and the write operation, thereby efficiently performing the column operations.

The controller 1300 may be based on the controller 10, illustrated in FIG. 1. Each of the semiconductor devices 1400(K:1) may be based on the semiconductor device 20, illustrated in FIG. 1. In some embodiments, each of the semiconductor devices 1400(K:1) may be based on any one of a dynamic random access memory (DRAM), a phase change random access memory (PRAM), a resistive random access memory (RRAM), a magnetic random access memory (MRAM), and a ferroelectric random access memory (FRAM).

What is claimed is:

1. A semiconductor device comprising:
a bank group control circuit configured to generate a bank group enablement signal, a first column control signal, and a second column control signal based on an internal command/address signal that is inputted while an internal chip selection signal has a first logic level; and
a bank group configured to include first to fourth banks,
wherein the bank group includes a common circuit to perform a column operation for at least two of the first to fourth banks based on the bank group enablement signal and the first and second column control signals.

2. The semiconductor device of claim 1,
wherein the internal chip selection signal is generated based on a chip selection signal, which is provided by an external device, in synchronization with a clock signal; and
wherein the internal command/address signal is generated based on a command/address signal, which is provided by the external device, in synchronization with the clock signal.

3. The semiconductor device of claim 1,
wherein the column operation for any one of the first and second banks is performed based on logic levels of the bank group enablement signal and the first column control signal; and
wherein the column operation for any one of the third and fourth banks is performed based on logic levels of the bank group enablement signal and the second column control signal.

4. The semiconductor device of claim 1, wherein the bank group control circuit includes:
a command decoder configured to decode the internal chip selection signal and the internal command/address signal to generate a write signal and a read signal, one of which is selectively enabled; and
a column control circuit configured to generate the bank group enablement signal and the first and second column control signals, after a predetermined period elapses, when the internal chip selection signal and the internal command/address signal are inputted when the write signal is enabled and configured to generate the bank group enablement signal and the first and second column control signals when the internal chip selection signal and the internal command/address signal are inputted when the read signal is enabled.

5. The semiconductor device of claim 4, wherein the column control circuit is configured to generate an internal address based on the internal command/address signal that is inputted while the internal chip selection signal has a second logic level when any one of the write signal and the read signal is enabled.

6. The semiconductor device of claim 5, wherein the column control circuit includes:
an address latch circuit configured to, when any one of the write signal and the read signal is enabled, generate a bank group address based on a first group of the internal command/address signal, generate a bank address based on a second group of the internal command/address signal while the internal chip selection signal has the first logic level, and generate an input command/address signal based on the internal command/address signal while the internal chip selection signal has the second logic level;
a shifting circuit configured to shift the write signal to generate a pre-shift signal and a shift signal, which are sequentially enabled; and
an internal address generation circuit configured to, when the read signal, the pre-shift signal, and the shift signal are enabled, generate the bank group enablement signal based on the bank group address, generate the first column control signal and the second column control signal based on the bank address, and generate the internal address based on the input command/address signal.

7. The semiconductor device of claim 6, wherein the internal address generation circuit includes:
a pipe circuit configured to generate an internal bank group address and an internal bank address based on the bank group address and the bank address when the read signal is enabled, configured to latch the bank group address and the bank address when the pre-shift signal is enabled, and configured to generate the internal bank group address and the internal bank address based on the latched bank group address and the latched bank address when the shift signal is enabled;
an address transfer circuit configured to, when any one of the read signal and the shift signal is enabled, generate the bank group enablement signal based on the internal bank group address and generate the first and second column control signals based on the internal bank address; and
an address decoder configured to decode the input command/address signal to generate the internal address when any one of the read signal and the shift signal is enabled.

8. The semiconductor device of claim 7, wherein the address transfer circuit includes:
a first logic circuit configured to generate the bank group enablement signal based on the internal bank group address when any one of the read signal and the shift signal is enabled;
a pulse generation circuit configured to generate a pulse signal with a pulse that is created when the internal bank group address with the first logic level is inputted when any one of the read signal and the shift signal is enabled;
a latch circuit configured to generate a transfer control signal that is disabled when a reset signal is inputted and enabled by the pulse of the pulse signal; and
a second logic circuit configured to generate the first column control signal and the second column control signal, one of which is selectively enabled based on a logic level of the internal bank address while the transfer control signal is enabled.

9. The semiconductor device of claim 1, wherein the bank group includes:
a first common circuit configured to be activated based on a logic level of the first column control signal to perform the column operation for the first and second banks;
a first internal control circuit configured to be activated based on logic levels of the first column control signal and the bank group enablement signal to perform the column operation for the first bank;
a second internal control circuit configured to be activated based on logic levels of the first column control signal and the bank group enablement signal to perform the column operation for the second bank;
a second common circuit configured to be activated based on a logic level of the second column control signal to perform the column operation for the third and fourth banks;
a third internal control circuit configured to be activated based on logic levels of the second column control signal and the bank group enablement signal to perform the column operation for the third bank; and
a fourth internal control circuit configured to be activated based on logic levels of the second column control signal and the bank group enablement signal to perform the column operation for the fourth bank.

10. The semiconductor device of claim 9,
wherein the first common circuit is located between the first and second banks; and
wherein the second common circuit is located between the third and fourth banks.

11. A semiconductor device comprising:
a bank group control circuit configured to generate a bank group enablement signal, a first column control signal, and a second column control signal based on an internal command/address signal that is inputted while an internal chip selection signal has a first logic level; and
a core circuit configured to include a first bank group and a second bank group,
wherein after any one of a first common circuit and a second common circuit, the first common circuit and the second common circuit being connected to banks of the first bank group, is activated by the bank group enablement signal and the first and second column control signals to perform a column operation, any one of a third common circuit and a fourth common circuit, the third common circuit and fourth second common circuit being connected to banks of the second bank group, is activated by the bank group enablement signal and the first and second column control signals to perform the column operation.

12. The semiconductor device of claim 11,
wherein the internal chip selection signal is generated based on a chip selection signal, which is provided by an external device, in synchronization with a clock signal; and
wherein the internal command/address signal is generated based on a command/address signal, which is provided by the external device, in synchronization with the clock signal.

13. The semiconductor device of claim 11,
wherein the first bank group includes first to fourth banks; and
wherein the second bank group includes fifth to eighth banks.

14. The semiconductor device of claim 13,
wherein the first and second banks share the first common circuit;
wherein the third and fourth banks share the second common circuit;
wherein the fifth and sixth banks share the third common circuit; and
wherein the seventh and eighth banks share the fourth common circuit.

15. The semiconductor device of claim 11, wherein the bank group control circuit includes:
a command decoder configured to decode the internal chip selection signal and the internal command/address signal to generate a write signal and a read signal, one of which is selectively enabled; and
a column control circuit configured to generate the bank group enablement signal and the first and second column control signals, after a predetermined period elapses, when the internal chip selection signal and the internal command/address signal are inputted when the write signal is enabled and configured to generate the bank group enablement signal and the first and second column control signals when the internal chip selection signal and the internal command/address signal are inputted when the read signal is enabled.

16. The semiconductor device of claim 15, wherein the column control circuit is configured to generate an internal address based on the internal command/address signal that is inputted while the internal chip selection signal has a second logic level when any one of the write signal and the read signal is enabled.

17. The semiconductor device of claim 16, wherein the column control circuit includes:
an address latch circuit configured to, when any one of the write signal and the read signal is enabled, generate a bank group address based on a first group of the internal command/address signal, generate a bank address based on a second group of the internal command/address signal while the internal chip selection signal has the first logic level, and generate an input command/address signal based on the internal command/address signal while the internal chip selection signal has the second logic level;
a shifting circuit configured to shift the write signal to generate a pre-shift signal and a shift signal, which are sequentially enabled; and
an internal address generation circuit configured to, when the read signal, the pre-shift signal, and the shift signal are enabled, generate the bank group enablement signal based on the bank group address, generate the first column control signal and the second column control signal based on the bank address, and generate the internal address based on the input command/address signal.

18. The semiconductor device of claim 17, wherein the internal address generation circuit includes:
a pipe circuit configured to generate an internal bank group address and an internal bank address based on the bank group address and the bank address when the read signal is enabled, configured to latch the bank group address and the bank address when the pre-shift signal is enabled, and configured to generate the internal bank group address and the internal bank address based on the latched bank group address and the latched bank address when the shift signal is enabled;
an address transfer circuit configured to, when any one of the read signal and the shift signal is enabled, generate the bank group enablement signal based on the internal bank group address and generate the first and second column control signals based on the internal bank address; and
an address decoder configured to decode the input command/address signal to generate the internal address when any one of the read signal and the shift signal is enabled.

19. The semiconductor device of claim 18, wherein the address transfer circuit includes:
a first logic circuit configured to generate the bank group enablement signal based on the internal bank group address when any one of the read signal and the shift signal is enabled;
a pulse generation circuit configured to generate a pulse signal with a pulse that is created when the internal bank group address with the first logic level is inputted when any one of the read signal and the shift signal is enabled;
a latch circuit configured to generate a transfer control signal that is disabled when a reset signal is inputted and enabled by the pulse of the pulse signal; and
a second logic circuit configured to generate the first column control signal and the second column control signal, one of which is selectively enabled based on a logic level of the internal bank address while the transfer control signal is enabled.

20. The semiconductor device of claim 11, wherein the first bank group includes:
the first common circuit configured to be activated based on a logic level of the first column control signal to perform the column operation for first and second banks that are included in the first bank group;
a first internal control circuit configured to be activated based on logic levels of the first column control signal and the bank group enablement signal to perform the column operation for the first bank;
a second internal control circuit configured to be activated based on logic levels of the first column control signal and the bank group enablement signal to perform the column operation for the second bank;
the second common circuit configured to be activated based on a logic level of the second column control signal to perform the column operation for third and fourth banks that are included in the first bank group;
a third internal control circuit configured to be activated based on logic levels of the second column control signal and the bank group enablement signal to perform the column operation for the third bank; and
a fourth internal control circuit configured to be activated based on logic levels of the second column control signal and the bank group enablement signal to perform the column operation for the fourth bank.

21. The semiconductor device of claim 20,
wherein the first common circuit is located between the first and second banks; and
wherein the second common circuit is located between the third and fourth banks.

22. The semiconductor device of claim 11, wherein the second bank group includes:
the third common circuit configured to be activated based on a logic level of the first column control signal to perform the column operation for fifth and sixth banks that are included in the second bank group;
a fifth internal control circuit configured to be activated based on logic levels of the first column control signal and the bank group enablement signal to perform the column operation for the fifth bank;
a sixth internal control circuit configured to be activated based on logic levels of the first column control signal and the bank group enablement signal to perform the column operation for the sixth bank;
the fourth common circuit configured to be activated based on a logic level of the second column control signal to perform the column operation for seventh and eighth banks that are included in the second bank group;
a seventh internal control circuit configured to be activated based on logic levels of the second column control signal and the bank group enablement signal to perform the column operation for the seventh bank; and
an eighth internal control circuit configured to be activated based on logic levels of the second column control signal and the bank group enablement signal to perform the column operation for the eighth bank.

23. The semiconductor device of claim 22,
wherein the third common circuit is located between the fifth and sixth banks; and
wherein the fourth common circuit is located between the seventh and eighth banks.
